(19) United States
(12) Patent Application Publication
(10) Pub. No.: US 2018/0317317 A1
(43) Pub. Date: Nov. 1, 2018

(54) GLASS WIRED SUBSTRATE AND POWER MODULE

(71) Applicant: SHARP KABUSHIKI KAISHA, Sakai City, Osaka (JP)

(72) Inventors: HIROYUKI NAKANISHI, Sakai City (JP); TOMOTOSHI SATOH, Sakai City (JP)

(73) Assignee: SHARP KABUSHIKI KAISHA, Sakai City ,Osaka (JP)

(21) Appl. No.: 15/770,154

(22) PCT Filed: Sep. 27, 2016
(86) PCT No.: PCT/JP2016/078377

§ 371 Date: Apr. 20, 2018

(30) Foreign Application Priority Data
Oct. 21, 2015 (JP) 2015-207309

(51) Int. Cl. H05K 1/02; H05K 1/18; H05K 1/14; H05K 1/11; H05K 1/03

(52) U.S. Cl. CPC H05K 1/0271; H05K 1/181; H05K 1/142; H05K 1/115; H05K 1/0306; H05K 2201/10522; H05K 2201/09609; H05K 2201/093; H05K 2201/09227; H05K 2201/10015; H05K 2201/10166; H05K 1/0201

(57) ABSTRACT

A glass wired substrate includes a glass support substrate having first and second surfaces. A first circuit unit is arranged on the first surface. A second circuit unit is arranged on the second surface On the second circuit unit, a trimmed pattern comprising a plurality of slits is formed.

### TECHNICAL FIELD

The present invention relates to a printed circuit board mounted with an electronic component including a semiconductor device.

### BACKGROUND ART

Conventionally, various power modules in each of which a plurality of power devices (semiconductor devices such as diodes, transistors, and thyristors) are mounted on a substrate have been designed. A power device is capable of handling a large current with a high voltage compared with a semiconductor device used in a computer, and thus may generate a high heat due to the high power condition. heat change of a power device has a risk of causing an operation failure of the power module. For this reason, efforts for improvement have been made to make a power module less prone to influence of a heat change of a power device.

For example, in order for a power device not to generate a high heat, efforts have been made to use a substrate with high heat conductivity, that is, a substrate with low heat resistance. Furthermore, for example, there have been efforts for enabling reduction of energy losses in the power module and efforts in designing for shortening the length of a wire arranged on one side of the substrate to reduce switching losses.

Patent Literature 1 discloses a metal-ceramic substrate in which metal members having different hardnesses, strengths, types, or thicknesses are bonded on both sides of a ceramic substrate and the metal member bonded on one side of the ceramic substrate is formed as a metal circuit plate. The substrate is formed so as to be warped concavely on the metal circuit side. Efforts of employing a low-heat material and a low-resistance material for materials of the substrate are thus made.

### CITATION LIST

### Patent Literature

PTL 1: Japanese Unexamined Patent Application Publication No. 2004-207587 (disclosed on Jul. 22, 2004)

### SUMMARY OF INVENTION

### Technical Problem

However, with the technique disclosed in Patent Literature 1, there is a problem that a fine adjustment is difficult in controlling the amount of warp of the ceramic substrate to a predetermined amount, and thus, the adjustment is troublesome, leading to an increase in the cost of the metal-ceramic substrate. The present invention aims to solve the above-described problem and provide a glass wired substrate that is cheap and has high durability against a heat change of an electronic component mounted on the substrate and other related features.

### Solution to Problem

To solve the above-described problem, a glass wired substrate according to an aspect of the present invention is a glass wired substrate mounted with an electronic component including a support substrate formed of glass, a first circuit unit arranged on a first surface of the support substrate, and a second circuit unit arranged on the substantially entire surface of a second surface of the support substrate that faces the first surface. The first circuit unit has an electrode unit electrically connected to the electronic component. On the second circuit unit, a trimmed pattern composed of a plurality of slits is formed.

### Advantageous Effects of Invention

According to an aspect of the present invention, a trimmed pattern composed of a plurality of slits is formed on the second circuit unit. With this, even when heat shocks have repeatedly been applied on the glass wired substrate, the glass wired substrate can disperse a stress due to the heat shocks that is caused by a difference between the heat expansion coefficient of the support substrate and the heat expansion coefficient of the second circuit unit while maintaining adhesion between the support substrate and the second circuit unit. This enables to prevent the support substrate formed of glass from being separated from the second circuit unit due to the heat shocks. As a result, durability against the heat shocks with respect to the glass wired substrate can be enhanced. Furthermore, glass, which is the material of the support substrate, is cheaper than the material of a ceramic substrate (alumina, for example) generated by sintering powders. Furthermore, forming a trimmed pattern on the second circuit unit is easier than the conventional technique that controls the amount of warp of the ceramic substrate to a stable amount. Consequently, a glass wired substrate that is cheap and has high reliability can be provided.

### BRIEF DESCRIPTION OF DRAWINGS

FIGS. 1(a) to 1(c) each are a diagram illustrating a glass wired substrate according to a first embodiment of the present invention.

FIG. 2 is a diagram illustrating a glass wired substrate according to a second embodiment of the present invention.

FIGS. 3(a) and 3(b) each are a diagram illustrating a grass wired substrate according to a third embodiment.

FIGS. 4(a) to 4(c) each are a diagram illustrating a ceramic wired substrate being a comparative example of the glass wired substrate.

FIGS. 5(a) to 5(c) each are a diagram illustrating a power module in which an electronic component is mounted on the ceramic wired substrate.

FIG. 6 is a diagram illustrating coupling of the power module illustrated in FIG. 5.

FIGS. 7(a) to 7(c) each are a diagram illustrating a ceramic wired substrate being another comparative example of the glass wired substrate.

FIGS. 8(a) to 8(c) each are a diagram illustrating a glass wired substrate being further another comparative example of the glass wired substrate.

FIG. 9 is a diagram illustrating an electric circuit in a power module in a state in which an electronic component is mounted on the glass wired substrate.

### DESCRIPTION OF EMBODIMENTS

An embodiment of the present invention will be described below in detail with reference to the drawings. However, the size, material, shape, relative arrangement, and the like of a component described in the embodiment merely represent an embodiment and the scope of the present invention should not be limitedly interpreted. Furthermore, when a configuration in a specific item described below is the same as a configuration explained in another item, the explanation thereof will be omitted in some cases. Furthermore, for convenience of explanation, a component having the same function as a component presented in another item will be denoted with the same reference sign and the explanation thereof will be omitted as appropriate.

### First Embodiment

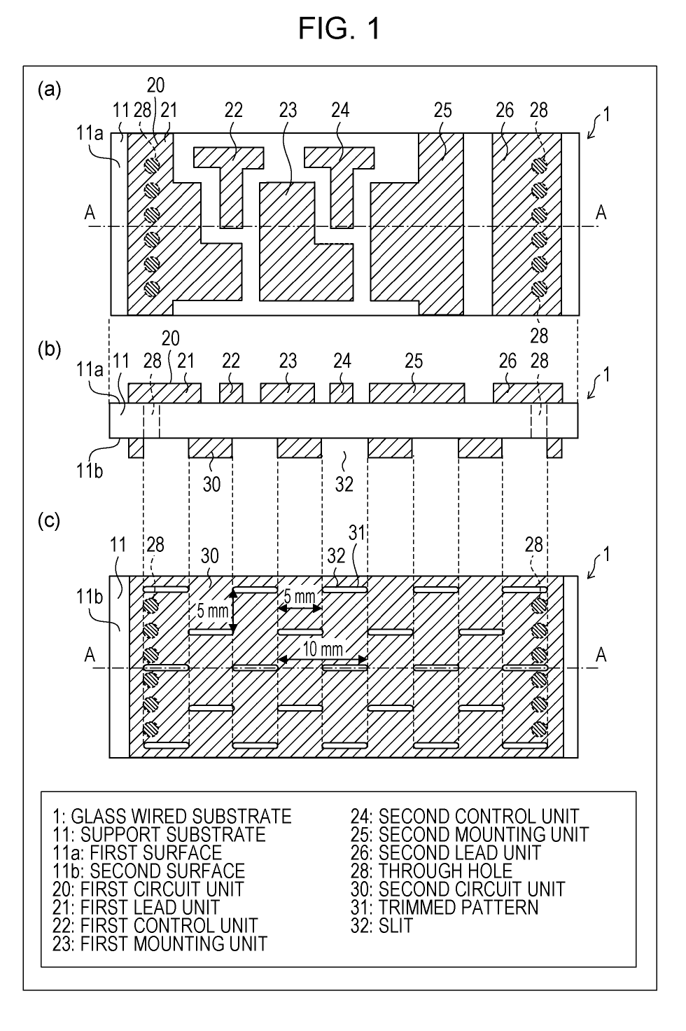

An embodiment of the present invention will be described below with reference to FIG. 1 and FIGS. 4 to 9. FIG. 1(a) is a top view of a glass wired substrate 1 according to a first embodiment of the present invention. FIG. 1(b) is a cross sectional view taken along the line A-A illustrated in FIG. 1(a). FIG. 1(c) is a bottom view of the glass wired substrate 1. It is to be noted that the aspect ratio of the glass wired substrate 1 illustrated in FIGS. 1(a) to 1(c) does not correctly present the size and the reduced scale described below.

As illustrated in FIG. 1, the glass wired substrate 1 includes a support substrate 11, a first circuit unit 20, and a second circuit unit 30. The support substrate 11 is a body of the glass wired substrate 1 and supports the first circuit unit 20 and the second circuit unit 30. The support substrate 11 is formed of glass having high heat resistance, high shock resistance, and high chemical resistance, for example, borosilicate glass. The size of the support substrate 11 is 20 mm in length, 50 mm in width, and 0.5 mm in thickness, for example. It is to be noted that in the description below, one surface of the support substrate 11 whose length is 20 mm and whose width is 50 mm is a first surface 11a, as illustrated in FIG. 1(a), and a surface of the support substrate 11 that faces the first surface 11a is a second surface 11b, as illustrated in FIG. 1(b).

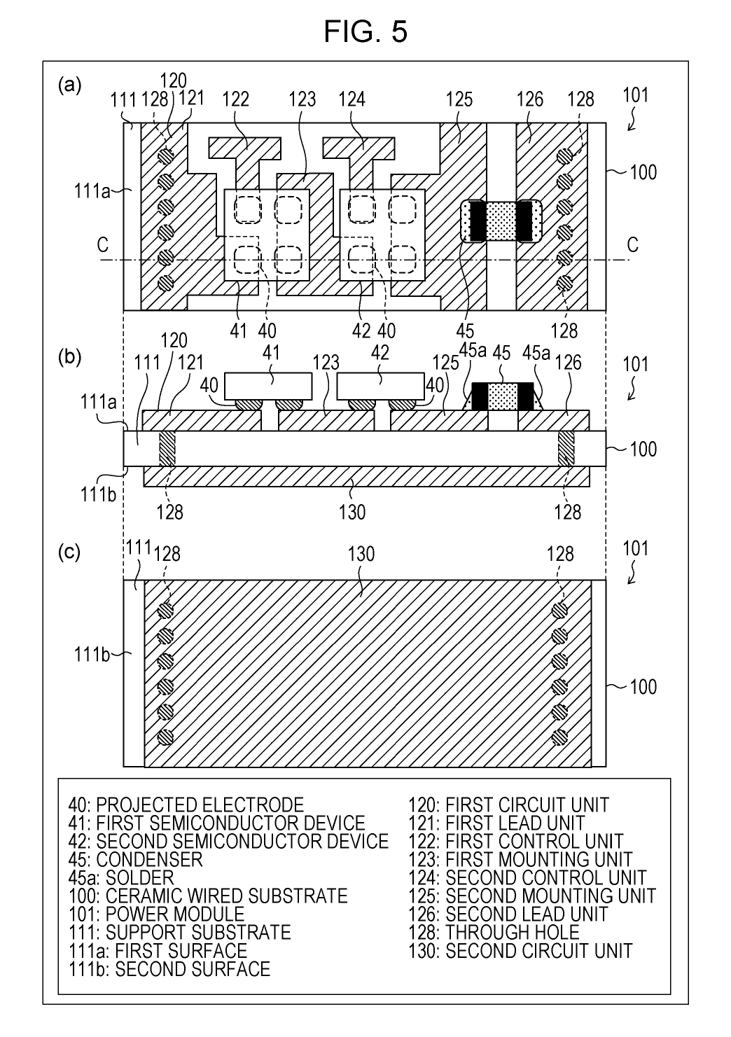

As illustrated in FIG. 1(a), the first circuit unit 20 is composed of six circuits (electrode units) arranged on the first surface 11a of the support substrate 11 and includes a first lead unit 21, a first control unit 22, a first mounting unit 23, a second control unit 24, a second mounting unit 25, and a second lead unit 26. It is to be noted that the six circuits 21 to 26 composing the first circuit unit 20 will be described with reference to FIG. 5.

For example, the first circuit unit 20 is a copper circuit unit formed by electroplating and is 0.07 mm in thickness. When the first circuit unit 20 (copper circuit unit) is formed, copper plating does not grow directly on the support substrate 11 formed of glass, and the first circuit unit 20 thus is formed mainly by patterning using sputtering film formation and a photolithography method and etching processing. That is to say, the first circuit unit 20 formed of copper is formed by sequentially performing processes described below (not illustrated). The first surface 11a of the support substrate 11 is treated with surface roughening processing with argon plasma. A copper thin film is formed by electroless plating on the first surface 11a. Resist application and patterning processing are performed. A copper thick film is formed by electroplating on a pattern opening on which resist has not been applied. Resist removal and etching processing of an exposed part of the copper thin film (a part of the copper thin film on which resist has been applied) are performed.

As illustrated in FIG. 1(c), the second circuit unit 30 is composed of one circuit arranged on the second surface lib of the support substrate 11 and is for applying a large current. The second circuit unit 30 is arranged on the second surface 11b of the support substrate 11 and has a function as a heat sink. On the second circuit unit 30, a trimmed pattern 31 which will be described later is formed. The second circuit unit 30 thus is not arranged on the entire surface of the second surface 11b but is arranged on the substantially entire surface of the second surface 11b. Furthermore, the second circuit unit 30 may be arranged on a part excluding both ends of the second surface 11b in the lateral direction (direction in which a current flows) of the second surface 11b. Furthermore, when a plurality of glass wired substrates 1 are coupled for use in the longitudinal direction (direction perpendicular to the direction in which a current flows) of the glass wired substrates 1, the second circuit unit 30 may be arranged on a part including the both ends of the second surface 11b in the longitudinal direction (direction perpendicular to the direction in which a current flows) of the second surface 11b so as to be connected to another second circuit unit 30 adjacent thereto.

Furthermore, on the second circuit unit 30, the trimmed pattern 31 is formed. The trimmed pattern 31 is composed of a plurality of slits 32 penetrating in the thickness direction of the second circuit unit 30. The plurality of slits 32 are arranged at fixed intervals (hereinafter, referred to as staggered arrangement).

For example, the size of the second circuit unit 30 is 20 mm in length, 50 mm in width, and 0.5 mm in thickness, similarly to the size of the first circuit unit 20. One slit 32 composing the trimmed pattern 31 forms a gap in a substantially rectangular shape of 5 mm in length in the lateral direction (direction in which a current flows) of the second circuit unit 30 and 1 mm in width in the longitudinal direction (direction perpendicular to the direction in which a current flows) of the second circuit unit 30. It is to be noted that a corner of the gap (vertex of the rectangle) may be a rounded curve, and the shape of the gap in the above-described width may be a semicircle whose radius is 0.5 mm. Furthermore, the plurality of slits 32 are formed at intervals of 5 mm in the lateral direction of the second circuit unit 30 and also formed at intervals of 5 mm in the longitudinal direction of the second circuit unit 30. That is to say, when it is assumed that a lateral array is composed by a plurality of slits formed at intervals of 5 mm in the lateral direction of the second circuit unit 30, the plurality of slits 32 forming the lateral array are arranged in the lateral direction of the second circuit unit 30 alternately with the slits 32 composing the lateral array that are apart therefrom by 5 mm in the longitudinal direction of the second circuit unit 30 (staggered arrangement). It is to be noted that the second circuit unit 30 is formed by the same processes as those for the first circuit unit 20.

As illustrated in FIG. 1(b), on both ends of the support substrate 11 in the lateral direction, a plurality of through holes 28 penetrating in the direction from the first surface 11a to the second surface 11b (the thickness direction of the support substrate 11) are formed. In the inside of each of the through holes 28, a metallic body is embedded, enabling the first lead unit 21 and the second lead unit 26 to be in an electrically connected state via the second circuit unit 30.

On each of the surfaces of the first circuit unit 20 and the second circuit unit 30, to prevent oxidation of a metal (copper) present on the surface, nickel is formed so as to make an electronic component such as a semiconductor device and a condenser easy to be mounted by soldering. On the nickel, gold is further formed. That is to say, on the support substrate 11 formed of glass, subsequent to copper electroplating, nickel electroplating and gold electroplating are applied in this order.

### COMPARATIVE EXAMPLE 1

Substrates for mounting semiconductor devices are roughly classified into rigid types having no flexibility and flexible types having flexibility. The former includes an epoxy substrate in which the substrate body is formed of an epoxy resin (for example, glass epoxy substrate generated by incorporating an epoxy resin into superimposed glass fiber cloths) and a ceramic substrate in which the substrate body is generated by sintering aluminum oxide or the like. The latter includes an organic polymer film substrate in which the substrate body is formed of polyimide, Kapton®, Upilex®, or the like, which is widely used.

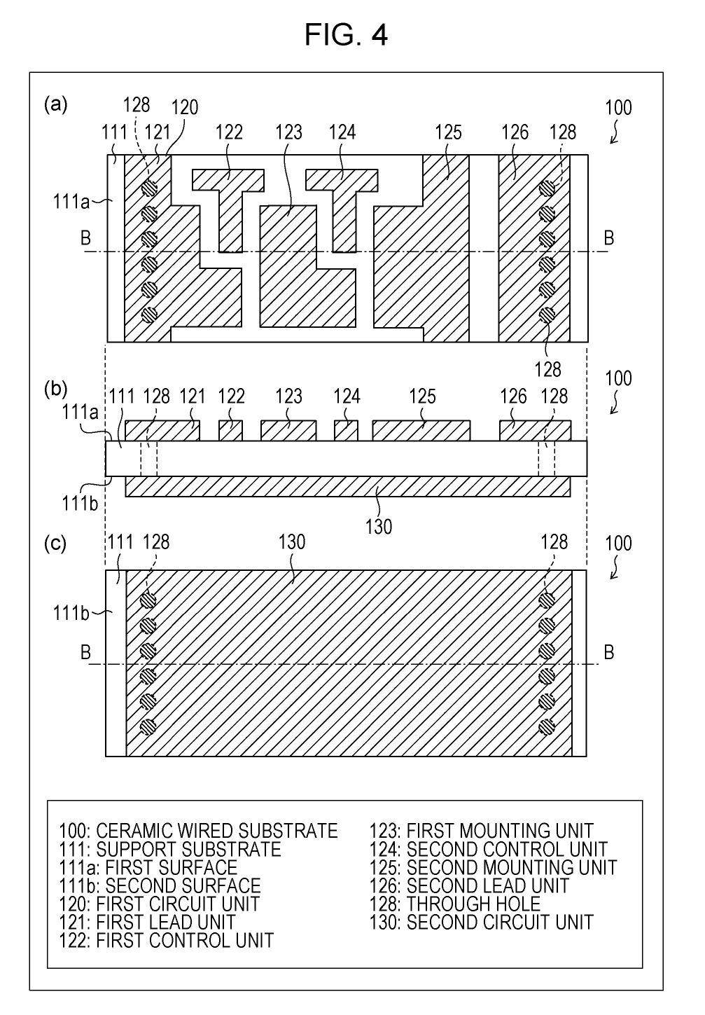

FIG. 4(a) is a top view of a ceramic wired substrate 100 being a comparative example of the glass wired substrate 1 illustrated in FIG. 1. FIG. 4(b) is a cross sectional view taken along the line B-B illustrated in FIG. 4(a). FIG. 4(c) is a bottom view of the ceramic wired substrate 100. The ceramic wired substrate 100 illustrated in FIG. 4 is different from the glass wired substrate 1 illustrated in FIG. 1 in that a support substrate 111 being the body of the ceramic wired substrate 100 is a ceramic substrate and no slit is formed on a second circuit unit 130 arranged on the surface of the support substrate 111.

As illustrated in FIG. 4(a), on a first surface 111a of the support substrate 111, a first circuit unit 120 is formed. The first circuit unit 120 is composed of six circuits, similarly to the first circuit unit 20 illustrated in FIG. 1, and includes a first lead unit 121, a first control unit 122, a first mounting unit 123, a second control unit 124, a second mounting unit 125, and a second lead unit 126. It is to be noted that the six circuits 121 to 126 composing the first circuit unit 120 will be described with reference to FIG. 5.

Furthermore, as illustrated in FIG. 4(c), on a second surface 111b of the support substrate 111, the second circuit unit 130 is arranged. The second circuit unit 130 is composed of one circuit and is for applying a large current, similarly to the second circuit unit 30 illustrated in FIG. 1(c). Furthermore, the second circuit unit 130 is arranged on the substantially entire surface of the second surface 111b of the support substrate 111 and has a function as a heat sink.

Furthermore, as illustrated in FIG. 4(b), on both ends of the support substrate 11 in the lateral direction, similarly to FIG. 1(b), a plurality of through holes 128 penetrating in the direction from the first surface 111a to the second surface 111b (the thickness direction of the support substrate 111) are formed. In the inside of each of the through holes 128, a metallic body is embedded, enabling the first lead unit 121 and the second lead unit 126 to be in an electrically connected state via the second circuit unit 30.

FIG. 5(a) is a top view of a power module 101 in a state in which an electronic component is mounted on the top surface of the ceramic wired substrate 100 illustrated in FIG. 4(a). FIG. 5(b) is a cross sectional view taken along the line C-C illustrated in FIG. 5(a). It is to be noted that the top surface of the ceramic wired substrate 100 is the surface of the ceramic wired substrate 100 that includes the first surface 111a of the support substrate 111. The electronic component mounted on the top surface of the ceramic wired substrate 100 is a first semiconductor device 41, a second semiconductor device 42, and a condenser 45, for example, as illustrated in FIG. 5(a).

On the surface of the first circuit unit 120 on which the first semiconductor device 41 is mounted, four projected electrodes 40 (commonly known as bumps) are provided. More specifically, one projected electrode 40 is provided on a surface of the first lead unit 121, one projected electrode 40 is provided on a surface of the first control unit 122, and two projected electrodes 40 are provided on a surface of the first mounting unit 123. With this, the first semiconductor device 41 can electrically connect the first lead unit 121, the first control unit 122, and the first mounting unit 123.

Similarly, on the surface of the first circuit unit 120 on which the second semiconductor device 42 is mounted, four projected electrodes 40 are provided. More specifically, one projected electrode 40 is provided on a surface of the second lead unit 126, one projected electrode 40 is provided on a surface of the second control unit 124, and two projected electrodes 40 are provided on a surface of the second mounting unit 125. With this, the second semiconductor device 42 can electrically connect the first mounting unit 123, the second control unit 124, and the second mounting unit 125. It is to be noted that the first semiconductor device 41 and the second semiconductor device 42 are connected to the first circuit unit 120 through flip chip connection.

The condenser 45 electrically connects the second mounting unit 125 and the second lead unit 126 by being fixed to the second circuit unit 120 with a solder 45a. It is to be noted that FIG. 5(c) is a bottom view of the state in which an electronic component is mounted on the top surface of the ceramic wired substrate 100 illustrated in FIG. 4(a) and is a view similar to the bottom view illustrated in FIG. 4(c).

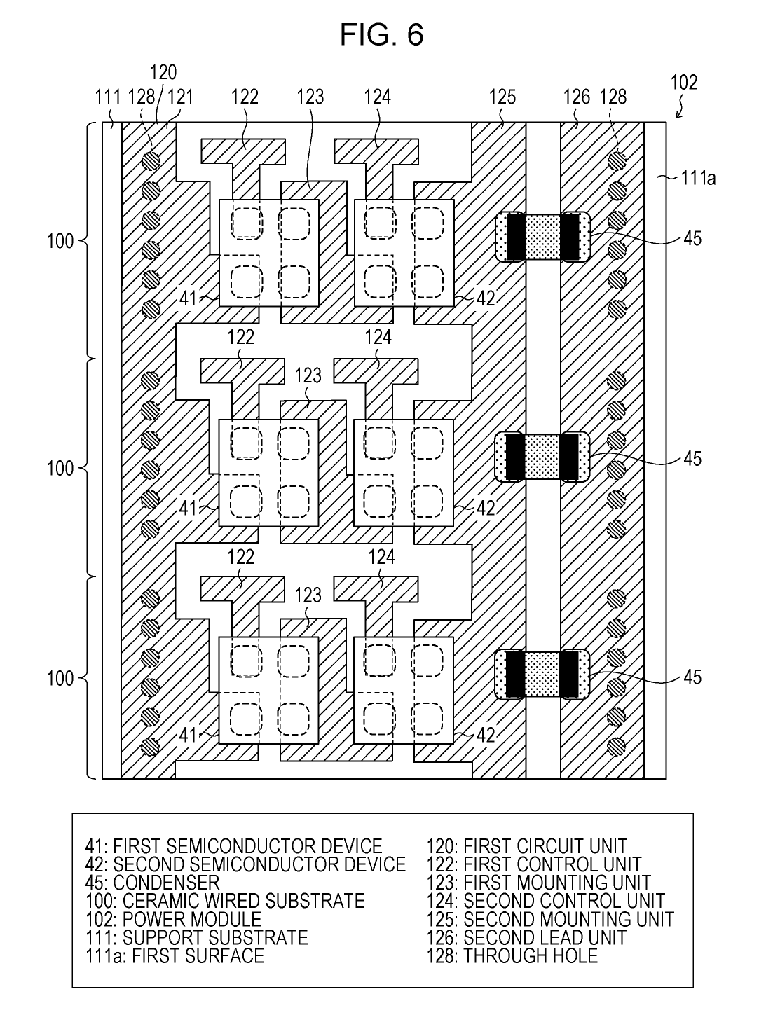

The ceramic wired substrate 100 in a state illustrated in FIG. 5 is used as a power module in a manner that a plurality of the ceramic wired substrates 100 are united. FIG. 6 is a top view of a power module 102 in which three power modules 101 illustrated in FIG. 5 are united. Three ceramic wired substrates 100 are adjacently united such that the through holes 128 formed at both ends of each ceramic wired substrate 100 in the lateral direction are continuously arrayed in a row.

The first semiconductor device 41 and the second semiconductor device 42 built in the power module 102 are power devices, for example, GaN type devices using gallium nitride (GaN). The GaN type devices have large band gaps compared with other types of semiconductor devices and can achieve higher electronic density due to a hetero junction, thus collecting attentions as built-in components in power modules.

When the first semiconductor device 41 illustrated in FIGS. 5 and 6 is a GaN-high electron mobility transistor (SENT) and the second semiconductor device 42 is a metal-oxide semiconductor field effect transistor (MOS-FET), the power module 102 illustrated in FIG. 6 is a three-phase inverter module. It is to be noted that the glass wired substrate 1 illustrated in FIG. 1 can be used as a power module in which an electronic component is mounted, similarly to the power module 101 illustrated in FIG. 5. Furthermore, the glass wired substrate 1 illustrated in FIG. 1 can be used as a power module in which a plurality of glass wired substrates 1 are united, similarly to the power module 102 illustrated in FIG. 6.

### COMPARATIVE EXAMPLE 2

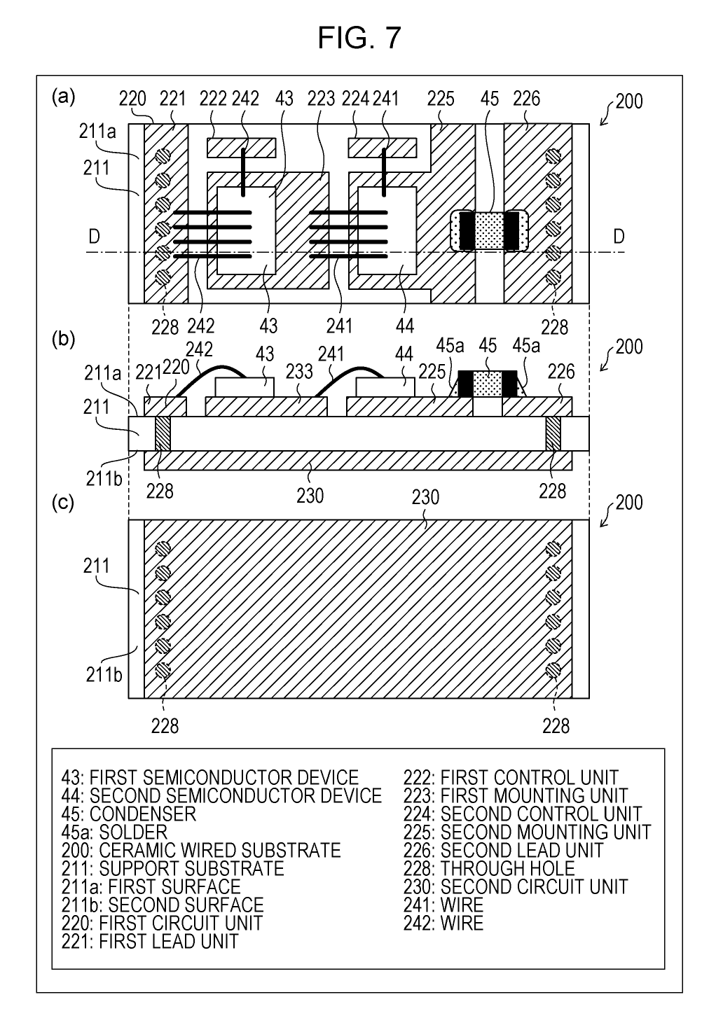

Furthermore, the semiconductor device mounted on the ceramic wired substrate may be connected via a wire to the circuit unit included in the ceramic wired substrate. FIG. 7(a) is a top view of a ceramic wired substrate 200 being another comparative example of the glass wired substrate 1 illustrated in FIG. 1. FIG. 7(b) is a cross sectional view taken along the line D-D illustrated in FIG. 7(a). FIG. 4(c) is a bottom view of the ceramic wired substrate 200. In the ceramic wired substrate 200 illustrated in FIG. 7(a), the shape of a first circuit unit 220 formed on a first surface 211a of a support substrate 211 being the body of the ceramic wired substrate 200 is different from the shape of the first circuit unit 120 illustrated in FIG. 5(a). It is to be noted that the first circuit unit 220 is formed by the same processes as those for the first circuit unit 20 described with reference to FIG. 1.

As illustrated in FIG. 7(a), the first circuit unit 220 is composed of six circuits and includes a first lead unit 221, a first control unit 222, a first mounting unit 223, a second control unit 224, a second mounting unit 225, and a second lead unit 226. To the first mounting unit 223, a first semiconductor device 43 is mounted. The first lead unit 221 and the first control unit 222 are connected to an electrode pad (not illustrated) included in the first semiconductor device 43 via a metal wire 242. Similarly, to the second mounting unit 225, a second semiconductor device 44 is mounted. The first mounting unit 223 and the second control unit 224 are connected to an electrode pad (not illustrated) included in the second semiconductor device 44 via a metal wire 241.

Furthermore, as illustrated in FIG. 7(b), in the inside of each of through holes 228 formed on the support substrate 211, a metallic body is embedded, enabling the first lead unit 221 and the second lead unit 226 to be in an electrically connected state via the second circuit unit 230, similarly to the through holes 128 illustrated in 5(b). It is to be noted that FIG. 7(c) is a view similar to the bottom view illustrated in FIG. 5(c). Furthermore, a ceramic wired substrate 200 illustrated in FIG. 7 is used in the power module formed by uniting a plurality of ceramic wired substrates 200, similarly to the power module 102 illustrated in FIG. 6.

### COMPARISON BETWEEN COMPARATIVE EXAMPLES 1 and 2

In FIGS. 4 to 7, comparison examples in each of which the support substrate is a ceramic wired substrate are presented. A power module in which the support substrate is a ceramic substrate tends to come at a higher cost than a power module in which the support substrate is a glass wired substrate. For this reason, it can be thought that a glass substrate is used as the support substrate to control the cost of the power module.

### Comparative Example 3

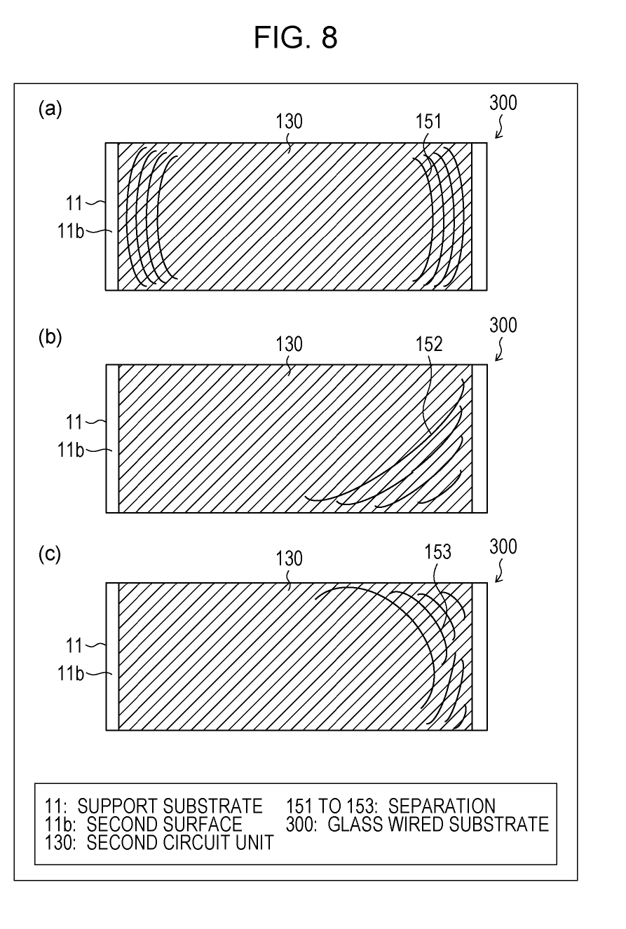

In a glass wired substrate 300 illustrated in FIGS. 8(a) to 8(c), the support substrate 111 being a ceramic substrate, which is the body of the ceramic wired substrate 100 illustrated in FIG. 4, has been changed to the support substrate 11 formed of glass. FIGS. 8(a) to 8(c) each are a bottom view of the glass wired substrate 300 being another comparative example of the glass wired substrate 1 illustrated in FIG. 1 and is a view after heat shocks have repeatedly been applied on the glass wired substrate 300. It is to be noted that the second circuit unit 130 is arranged on the substantially entire surface of the second surface 11b of the support substrate 11 and no slit is formed on the second circuit unit 130.

When heat shocks have repeatedly been applied on the glass wired substrate 300, separations 151 to 153 are generated between the second surface 11b of the support substrate 11 and the second circuit unit 130. The separations 151 to 153 illustrated in FIGS. 8(a) to 8(c) are obtained by conducting temperature cycle tests on the glass wired substrate 300, in which temperature changes from −55° C. to 150° C. and temperature changes from 150° C. to −55° C. have repeatedly been made.

Many of the separations 151 to 153 are generated at corner parts of the second surface 11b, on the second surface 11b of the support substrate 11. Furthermore, the number of the separations 151 to 153 tends to increase toward the center of the second surface 11b of the support substrate 11 (as if layers are formed in a growth ring) as the number of the temperature change cycles increases.

The separations 151 to 153 are caused by a difference between the heat expansion coefficient of the second circuit unit 130 and the heat expansion coefficient of the support substrate 11. For example, the heat expansion coefficient of the support substrate 11 formed of borosilicate glass is approximately 3×10⁻⁶, which makes a larger difference with the heat expansion coefficient of the second circuit unit 130 formed of metal (heat expansion coefficient of copper: approximately 16.6×10⁻⁶/° C.), compared with the heat expansion coefficient of a ceramic substrate formed of alumina, which is approximately 7×10⁻⁶/° C. Furthermore, on the second surface 11b of the support substrate 11, surface roughening processing has been applied for the purpose of forming the second circuit unit 130, and thus the adhesion between the second surface 11b of the support substrate 11 and the second circuit unit 130 is tight. For these reasons, when heat shocks have repeatedly been applied on the glass wired substrate 300, as separating from the center of the glass wired substrate 300, a stress due to the heat shocks generated on the glass wired substrate 300 becomes larger, accumulating on the surface layer of the support substrate 11. The separations 151 to 153 looking like wrinkles thus are generated on positions where accumulated stresses are concentrated (corner parts of the second surface 11b of the support substrate 11).

It is to be noted that the material of the support substrate 11 may be soda-lime glass, not borosilicate glass. The heat expansion coefficient of the support substrate formed of soda-lime glass is approximately 9×10⁻⁶/° C., which is slightly larger than that of a ceramic substrate (alumina) and rather closer to the heat expansion coefficient of the second circuit unit 130 (copper). This makes the support substrate formed of soda-lime glass less prone to a stress due to temperature change. However, soda-lime glass contains sodium, and thus it is hard to use soda-lime glass for an electronic material (particularly, power device).

### COMPARISON AND EFFECT OF COMPARATIVE EXAMPLE 3

In the glass wired substrate 1 presented in FIG. 1(c), the trimmed pattern 31 composed of a plurality of slits 32 is formed on the second circuit unit 30. With this, even when heat shocks have repeatedly been applied on the glass wired substrate 1, the glass wired substrate I can disperse a stress generated on the glass wired substrate 1 that is caused by a difference between the heat expansion coefficient of the support substrate 1 and the heat expansion coefficient of the second circuit unit 30 while maintaining adhesion between the support substrate 11 and the second circuit unit 30. That is to say, the stress does not accumulate on a specific part (for example, a corner part of the second surface 11b of the support substrate 11). For this reason, with respect to the glass wired substrate 1 including the second circuit unit 30 on which the trimmed pattern 31 is formed, even when heat shocks have repeatedly been applied on the glass wired substrate 1, separation between the second surface 11b of the support substrate 11 and the second circuit unit 30 is less likely to occur. As a result, an operation failure of the glass wired substrate 1 can be prevented. Particularly, when a plurality of slits 32 are formed on the second circuit unit 30 with a uniform density, as illustrated in FIG. 1(a), the trimmed pattern 31 in staggered arrangement is effective for dispersing a stress due to the heat shocks. Furthermore, this enables to prevent the support substrate 11 formed of glass from being damaged due to a stress generated on the glass wired substrate 1 that is caused by a difference between the heat expansion coefficient of the support substrate 1 and the heat expansion coefficient of the second circuit unit 30.

Furthermore, the stress due to the heat shocks tends to be concentrated on a vertex of a polygon. However, as illustrated in FIG. 1(c), the border line between a slit 32 and the second circuit unit 30 is a smooth curve, enabling to disperse the stress generated on the glass wired substrate 1 due to the heat shocks.

Furthermore, the longitudinal direction of the slit 32 formed on the second circuit unit 30 is the same as the direction in which a current flows in the second circuit unit 30. This enables to control an increase in electric resistance of the second circuit unit 30 that is caused by the trimmed pattern 31 formed on the second circuit unit 30. It is to be noted that the direction of a current flowing on the first surface 11a of the support substrate 11 and the direction of a current flowing on the second surface 11b of the support substrate 11 may be reversed in circulating the currents to cancel the influence on each other by an electric field generated on the support substrate 11.

Furthermore, when a power module capable of handling a large current is required, the power module may be structured by coupling a plurality of glass wired substrates 1 illustrated in FIG. 1 to be united, similarly to the power module 102 illustrated in FIG. 6. By coupling a plurality of glass wired substrates 1, each of the second circuit units 30 adjacent to each other of the glass wired substrates 1 is coupled to each other, whereby the power module can handle a large current. It is to be noted that by coupling a plurality of the glass wired substrates 1, also with respect to the first lead units 21 and the second lead units, adjacent ones in the adjacent glass wired substrates 1 are coupled to each other. Furthermore, because the plurality of glass wired substrates 1 are coupled, a stress generated on the power module due to repeatedly applied heat shocks can be dispersed onto each of the plurality of the glass wired substrates 1. As a result, an operation failure of the power module can be prevented.

Furthermore, in general, glass has lower heat conductivity than ceramic. For example, the heat conductivity of borosilicate glass is approximately 1 W/m·K and the heat conductivity of ceramic is approximately 200 W/m·K. For this reason, the support substrate 11 formed of glass is effective as a support substrate of a wired substrate on which a power device with high electric consumption and high heat generation is mounted. Furthermore, glass has certain rigidity and thus can maintain long-term stability as a material of the support substrate 11.

Furthermore, in general, a surface of glass has better flatness than that of ceramic. For this reason, when a semiconductor device is mounted on the glass wired substrate 1 through the above-described flip chip connection, the semiconductor device can be prevented from being unstably fixed in a tilted manner on the surface of the support substrate 11. This enables to provide a glass wired substrate 1 with high quality.

Furthermore, whereas the Young's modulus of ceramic formed of alumina is approximately 360 GPa, the Young's modulus of borosilicate glass is approximately 73 GPa. With this, a support substrate formed of glass is bent more easily and has a greater function to alleviate a bending stress by warping when the bending stress is applied thereon, compared with a ceramic substrate having the same thickness as that of the support substrate. For this reason, when a support substrate formed of glass is included in a glass wired substrate, damage on the glass wired substrate can be prevented even if some kind of force is applied on the glass wired substrate.

### (Summary of Electric Circuit)

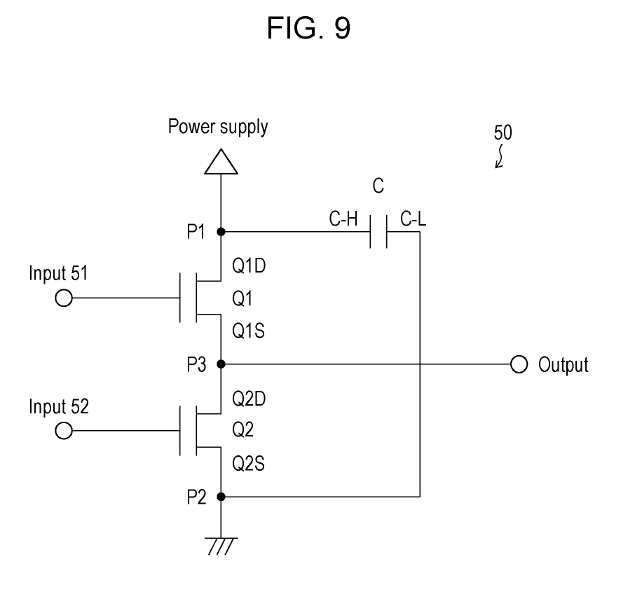

Next, an electric circuit 50 (hereinafter, referred to as a circuit) in a power module in a state in which an electronic component is mounted on the glass wired substrate 1 will be described with reference to FIG. 9. The circuit 50 is a half-bridge circuit being a base of a three-phase inverter, a full bridge (single-phase inverter), and the like. It is to be noted that the circuit diagram illustrated in FIG. 9 is also applied for the ceramic wired substrates illustrated in FIGS. 5 and 7.

A switching element Q1 connected to Input 51 is used to perform switching between a power supply (positive side) and OUTPUT. Similarly, a switching element Q2 connected to Input 52 is used to perform switching between a ground (negative side) and OUTPUT. Timings of Input 51 and Input 52 are adjusted such that the switching element Q1 and the switching element Q2 are not conducted at the same time on the operation of the circuit 50.

When the switching element Q1 or Q2 performs a switching operation, a noise is generated accompanied by switching. A bypass condenser C absorbs the noise and stabilizes the operation of the circuit 50. When the bypass condenser C absorbs the noise, a path from a connection point P1 toward a connection point P2 and a path from the connection point P2 toward the connection point P1 via electrodes (C-L, C-H) of the bypass condenser C are directed opposite to each other. Furthermore, the first circuit unit 20 and the second circuit unit 30 illustrated in FIG. 1 are arranged on the support substrate 11 such that an overlapped part of the two paths is large, whereby electric fields generated on both of the two paths cancel each other. With this canceling effect, parasitic inductance becomes apparently small, whereby the noise can be absorbed effectively with the bypass condenser C.

As wiring for guiding an effect of absorbing the noise, a first circuit unit is formed on the front surface of an insulating substrate and a second circuit unit is formed on the rear surface of the insulating substrate facing the front surface. The first circuit unit has a pattern that connects from the electrode C-H of the bypass condenser C to the connection point P2 via the connection point P1, a drain Q1D of the switching element Q1, a source Q1S of the switching element Q1, a connection point P3, a drain Q2D of the switching element Q2, and a source Q2S of the switching element Q2. The second circuit unit has a pattern that connects from the connection point P2 to the electrode C-L of the bypass condenser C.

For example, the second mounting unit 25 illustrated in FIG. 1 corresponds to the electrode C-H of the bypass condenser C, the connection point P1, and the drain Q1D of the switching element Q1 illustrated in FIG. 9. The first mounting unit 23 illustrated in FIG. 1 corresponds to the source Q1S of the switching element Q1, a connection point P3, the drain Q2D of the switching element Q2 illustrated in FIG. 9. The first lead unit 21 illustrated in FIG. 1 corresponds to the source Q2S of the switching element Q2 and the connection point P2 illustrated in FIG. 9. The through holes 28 formed on the first lead unit 21 and the through holes 28 formed on the second circuit unit 30 and the second lead unit 26 illustrated in FIG. 1 correspond to the pattern that connects from the connection point P2 to the electrode C-L of the bypass condenser C illustrated in FIG. 9.

### Second Embodiment

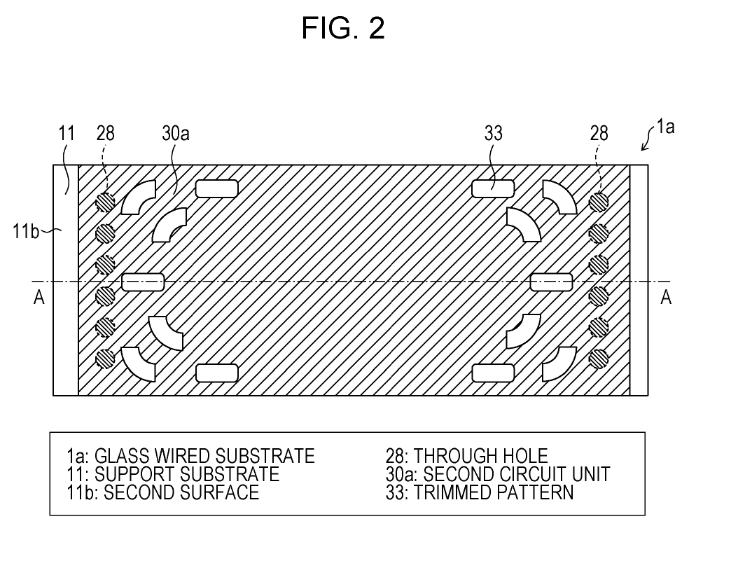

Next, another embodiment of the glass wired substrate 1 described in the first embodiment will be described with reference to FIG. 2. FIG. 2 is a bottom view of a glass wired substrate 1a according to a second embodiment. In the glass wired substrate 1a according to the present embodiment, a trimmed pattern 33 formed on a second circuit unit 30a is different from the trimmed pattern 31 of the glass wired substrate 1 according to the first embodiment (see FIG. 1(c)). It is to be noted that other features of the configuration of the glass wired substrate 1a are the same as those of the glass wired substrate 1 according to the first embodiment, and thus the descriptions thereof will be omitted in the present embodiment.

The trimmed pattern 33 illustrated in FIG. 2 is composed of a plurality of slits formed concentratedly on the periphery of the support substrate 11 where a stress due to heat shocks tends to apply (corner parts of the second circuit unit 30a). That is to say, with respect to the trimmed pattern 33, the plurality of slits are provided concentratedly on the end parts of the second circuit unit 30a. Particularly, the trimmed pattern 33 illustrated in FIG. 2 is effective for preventing the separation 151 illustrated in FIG. 8(a).

For example, on the corner parts of the second circuit unit 30a, arc-shaped slits centering on the center of the second circuit unit 30a are formed. Furthermore, on the line A′-A′ which is parallel to the direction in which a current flows (the longitudinal direction of the second circuit unit 30a, the lateral direction on the paper face) and passes through the center of the second circuit unit 30a, slits parallel to the above-described direction are formed.

Because the trimmed pattern 33 is formed on the second circuit unit 30a, a stress generated on the glass wired substrate 1 due to repeatedly applied heat shocks is dispersed. With this, the stress does not accumulate on a specific part of the support substrate 11 (for example, a corner part of the support substrate 11). For this reason, even when heat shocks have repeatedly been applied on the glass wired substrate 1a, separation between the second surface 11b of the support substrate 11 and the second circuit unit 30a is less likely to occur. As a result, an operation failure of the glass wired substrate 1a can be prevented.

Furthermore, by designing a border line between a slit forming a trimmed pattern 34 and the second circuit unit 30a to be a smooth curve, the stress generated on the glass wired substrate 1a due to the heat shocks can be more securely dispersed.

### Third Embodiment

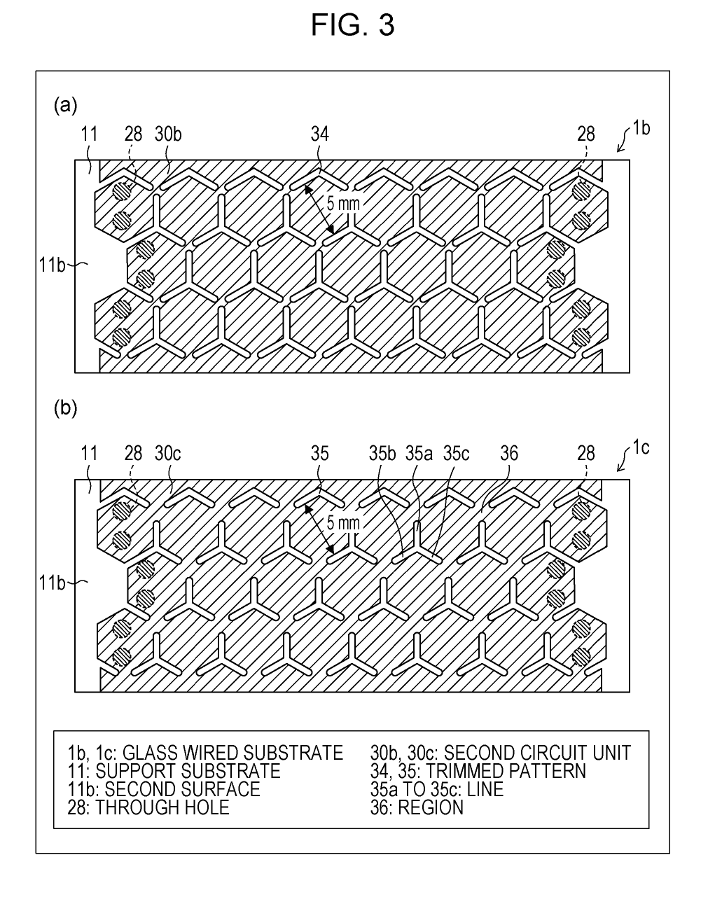

Next, further another embodiment of the glass wired substrate 1 will be described with reference to FIGS. 3(a) and (b). FIG. 3(a) is a bottom view of a glass wired substrate 1b according to a third embodiment. In the glass wired substrate 1b according to the present embodiment, a trimmed pattern 34 formed on a second circuit unit 30b is different from the trimmed pattern 31 of the glass wired substrate 1 according to the first embodiment (see FIG. 1(c)). It is to be noted that other features of the configuration of the glass wired substrate 1b are the same as those of the glass wired substrate 1 according to the first embodiment, and thus the descriptions thereof will be omitted in the present embodiment.

The trimmed pattern 34 illustrated in FIG. 3(a) is composed of a plurality of slits. Each of the slits is a gap that draws three lines connecting the center of a regular triangle and the vertices of the regular triangle. The plurality of slits are formed on the second circuit unit 30b at regular intervals so as to draw regular hexagons. With the trimmed pattern 34, the second circuit unit 30b has a honeycomb structure (structure in which a plurality of regular hexagons are arranged). For example, the distance between sides facing each other of each regular hexagon is 5 mm. It is to be noted that the plurality of slits composing the trimmed pattern 34 are formed so as to be apart from one another.

By designing the second circuit unit 30b to have a honeycomb structure, a stress generated on the glass wired substrate 1b due to repeatedly applied heat shocks can be dispersed. Furthermore, because the second circuit unit 30b has a honeycomb structure, even when the trimmed pattern 34 is formed on the second circuit unit 30b, the strength of the second circuit unit 30b is less likely to be damaged. As a result, the glass wired substrate 1b including the second circuit unit 30b can provide an environment in which the electronic component mounted on the glass wired substrate 1b can be stably operated.

Furthermore, by designing a border line between a slit forming a trimmed pattern 35 and the second circuit unit 30b to be a smooth curve, the stress generated on the glass wired substrate 1b due to the heat shocks can be more securely dispersed.

### (Variation)

The slits composing the trimmed pattern 34 illustrated in FIG. 3(a) have optional sizes. FIG. 3(b) is a bottom view of a glass wired substrate 1c being a variation of the glass wired substrate 1b illustrated in FIG. 3(a). For example, the slits composing the trimmed pattern 35 illustrated in FIG. 3(b) draw lines 35a to 35c which are shorter than those of the slits composing the trimmed pattern 34 illustrated in FIG. 3(a). With this, the part of the second circuit unit 30c that is cut to form the trimmed pattern 35 is reduced, enabling to widen a region 36 of the second circuit unit 30c which corresponds to the three vertices of the regular hexagon. For this reason, a current easily flows in the second circuit unit 30c.

### [Summary]

A glass wired substrate (1, 1a to 1c) according to a first aspect of the present invention is a glass wired substrate mounted with an electronic component (first semiconductor devices 41 and 43, second semiconductor devices 42 and 44, and a condenser 45) including a support substrate (11) formed of glass, a first circuit unit (20) arranged on a first surface (11a) of the support substrate, and a second circuit unit (30) arranged on the substantially entire surface of a second surface (11b) of the support substrate that faces the first surface. The first circuit unit has an electrode unit (a first control unit 22, a first mounting unit 23, a second control unit 24, a second mounting unit 25, and a second lead unit 26) electrically connected to the electronic component. On the second circuit unit, a trimmed pattern (31, 33 to 35) composed of a plurality of slits (32) is formed.

According to the above-described configuration, a trimmed pattern composed of a plurality of slits is formed on the second circuit unit. With this, even when heat shocks have repeatedly been applied on the glass wired substrate, the glass wired substrate can disperse a stress due to the heat shocks that is caused by a difference between the heat expansion coefficient of the support substrate and the heat expansion coefficient of the second circuit unit while maintaining adhesion between the support substrate and the second circuit unit. This enables to prevent the support substrate formed of glass from being separated from the second circuit unit due to the heat shocks. As a result, durability against the heat shocks with respect to the glass wired substrate can be enhanced. Furthermore, glass, which is the material of the support substrate, is cheaper than the material of a ceramic substrate (alumina, for example) generated by sintering powders. Furthermore, forming a trimmed pattern on the second circuit unit is easier than the conventional technique that controls the amount of warp of the ceramic substrate to a stable amount. Consequently, a glass wired substrate that is cheap and has high reliability can be provided.

In a glass wired substrate according to a second aspect of the present invention, in the above-described first aspect, the longitudinal direction of the slits may be the same as the direction of a current flowing in the second circuit unit. The above-described configuration enables to control an increase in electric resistance of the second circuit unit that is caused by the trimmed pattern formed on the second circuit unit. With this, a decrease in the amount of currents flowing in the second circuit unit can be prevented. As a result, a glass wired substrate mounted with an electronic component can be used as a power module.

In a glass wired substrate according to a third aspect of the present invention, in the above-described first aspect or second aspect, the plurality of slits may be formed in staggered arrangement. According to the above-described configuration, the glass wired substrate can effectively disperse a stress due to heat shocks. This enables to securely prevent the support substrate formed of glass from being separated from the second circuit unit due to the heat shocks.

In a glass wired substrate according to a fourth aspect of the present invention, in the above-described first aspect, the plurality of slits may be formed on corner parts of the second circuit unit. According to the above-described configuration, a stress generated on the glass wired substrate due to repeatedly applied heat shocks can be dispersed. With this, the stress does not accumulate on a specific part of the support substrate (a part of the support substrate that corresponds to a corner part of the second circuit unit on which the slits are formed). For this reason, even when heat shocks have repeatedly been applied on the glass wired substrate, separation between the support substrate and the second circuit unit is less likely to occur. As a result, an operation failure of the glass wired substrate can be prevented.

In a glass wired substrate according to a fifth aspect of the present invention, in the above-described first aspect, the second circuit unit may have a honeycomb structure formed by arranging a plurality of regular hexagons with the trimmed pattern. According to the above-described configuration, a stress generated on the glass wired substrate due to repeatedly applied heat shocks can be dispersed. Furthermore, because the second circuit unit has a honeycomb structure, even when the trimmed pattern is formed on the second circuit unit, the strength of the second circuit unit is less likely to be damaged. As a result, the glass wired substrate including the second circuit unit can provide an environment in which the electronic component mounted on the glass wired substrate can be stably operated.

In a glass wired substrate according to a sixth aspect of the present invention, in any one of the above-described first aspect to fifth aspect, each of the slits may have a shape with a vertex of a polygon being curved. According to the above-described configuration, each of the slits has a shape with a vertex of a polygon being curved. In general, a stress due to heat shocks tends to be concentrated on a vertex of a polygon. For this reason, by designing the shape of the slits to have a smooth curve, the stress generated on the glass wired substrate due to the heat shocks can be more securely dispersed.

In a glass wired substrate according to a seventh aspect of the present invention, in any one of the above-described first aspect to sixth aspect, the support substrate may be formed of borosilicate glass. According to the above-described configuration, because the support substrate is formed of borosilicate glass, the support substrate can be an insulator. With this, the glass wired substrate may be used with an electronic component mounted thereon.

In a power module (101) according to an eighth aspect of the present invention, the glass wired substrate described in any one of the above-described first aspect to seventh aspect may be mounted with the electronic component. According to the above-described configuration, the same effect as in the above-described first aspect to seventh aspect is achieved.

In a power module (102) according to a ninth aspect of the present invention, in the above-described eighth aspect, a plurality of the glass wired substrates mounted with the electronic component may be coupled to one another. According to the above-described configuration, by coupling a plurality of the glass wired substrates, each of the second circuit units adjacent to each other of the glass wired substrates is coupled to each other, whereby the power module can handle a large current. Furthermore, because the plurality of glass wired substrates are coupled, a stress generated on the power module due to repeatedly applied heat shocks can be dispersed onto each of the plurality of the glass wired substrates. For this reason, in each of the grass wired substrates composing the power module, the support substrate is prevented from being separated from the second circuit unit. As a result, an operation failure of the power module can be prevented.

### [Supplementary Note]

The present invention is not limited to the above-described embodiments, and various changes are possible within the scope presented in the claims. An embodiment obtained by combining as appropriate technical means disclosed in different embodiments is to be included in the technical scope of the present invention. Furthermore, by combining technical means disclosed in different embodiments, a new technical feature may be formed.

### INDUSTRIAL APPLICABILITY

The present invention may be used as a power system switching module mainly used in consumer equipment or industrial equipment.

### REFERENCE SIGNS LIST

1, 1a to 1c, 300 glass wired substrate

11 support substrate

11a first surface

11b second surface

20 first circuit unit

30 second circuit unit

31, 33 to 35 trimmed pattern

32 slit

41, 43 first semiconductor device (electronic component)

42, 44 second semiconductor device (electronic component)

45 condenser (electronic component)

101, 102 power module

151 to 153 separation

1. A glass wired substrate for mounting with an electronic component, the glass wired substrate comprising:
a glass support substrate having first and second opposite surfaces;
a first circuit unit arranged on the first surface of the glass support substrate; and
a second circuit unit arranged on substantially the entire second surface of the glass support substrate, wherein
the first circuit unit has an electrode unit for electrically connecting to an electronic component, and
on the second circuit unit, a trimmed pattern comprising a plurality of slits is formed;
wherein longitudinal direction of the slits is the same as the direction of a current flowing in the second circuit unit.

2. (canceled)

3. The glass wired substrate according to claim 1, wherein
the plurality of slits are staggered.

4. The glass wired substrate according to claim 1, wherein
the plurality of slits are formed on corner parts of the second circuit unit.

5. A power module for mounting with an electronic component having the glass wired substrate according to claim 1, wherein
the power module is used in a manner that a plurality of the power modules are coupled to one another.
